(19) United States
(12) Patent Application Publication
(10) Pub. No.: US 2006/0118159 A1
(43) Pub. Date: Jun. 8, 2006

(54) Thermoelectric direct conversion device

(75) Inventors: Osamu Tsuneoka, Setagaya-Ku (JP); Naruhito Kondo, Kawasaki-Shi (JP); Naokazu Iwanade, Itabashi-Ku (JP); Akihiro Hara, Yokohama-Shi (JP); Kazuki Tateyama, Yokohama-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/256,158

(22) Filed: Oct. 24, 2005

(30) Foreign Application Priority Data
Oct. 29, 2004 (JP) 2004-317324

(51) Int. Cl. H01L 35/28

(52) U.S. Cl. 136/211; 136/212

(57) ABSTRACT

A thermoelectric direct conversion device is foemed of a plurality of thermoelectric direct conversion semiconductor pairs each including a p-type semiconductor and an n-type semiconductor; a plurality of high-temperature electrodes and a plurality of low-temperature electrodes each electrically connecting the p-type semiconductor and the n-type semiconductor; a high-temperature insulating plate and a low-temperature insulating plate each thermally connected to the plurality of thermoelectric direct conversion semiconductor pairs via the plurality of high-temperature electrodes and the plurality of low-temperature electrodes, respectively; at least one diffusion barrier layer is disposed between the high- or low-temperature electrodes and the thermoelectric direct conversion semiconductor pairs, and the entire device is hermetically sealed up within an airtight case containing a vacuum or inert gas atmosphere, whereby diffusion between the electrodes and the semiconductor pairs is prevented to provide a thermoelectric conversion devise exhibiting excellent power generation performances for a long time period.

### BACKGROUND OF THE INVENTION

1. Field of the Invention

The present invention relates to a thermoelectric direct conversion device, and particularly to a thermoelectric direct conversion device that can maintain the mechanical characteristics or the electrical characteristics of its components and excellent conversion efficiency over a long period of time.

2. Description of the Related Art

An unprecedentedly rapid increase in the energy consumption in recent years has caused global warming due to the greenhouse gases, such as carbon dioxide (CO₂). It has globally become necessary and urgently imperative to exploit an energy source that can reduce the emission of CO₂ for global environmental conservation. In such a situation, principally from an energy-saving point of view, waste heat in a large scale has been recovered and reused. Furthermore, reuse of waste heat even in a small to a medium scale is also receiving attention.

However, waste heat in a small to a medium scale is relatively low in calories, even if it is of high quality. Accordingly, if a large-scale electric power plant for waste heat, such as a steam turbine, for example, applied thereto, huge equipment is required for such a small amount of heat, so that the power generation efficiency becomes extremely low, and a quantity of electricity compensating for the costs of the modification of existing facilities and the maintenance and repair costs, cannot be attained.

Furthermore, utilization of a heat source, such as hot water, is not realized in many cases, owing to the small amount of calories. Thus, it is a present state throughout the world that the utilization of waste heat in a small to a medium scale cannot be readily advanced. Hence, there is an increasing demand for the development and commercialization of a thermoelectric direct conversion device that can convert the waste heat in a small to a medium scale into electrical energy with a simple and small system.

A thermoelectric direct conversion device for directly converting thermal energy into electrical energy with a semiconductor has been developed to address such a technical demand (for example, see JP-A 2004-119833 and “Netsudenhenkankogaku: Kiso to Oyo” (Thermoelectric Conversion Engineering: Fundamentals and Applications), Realize K. K., pp. 349-363 (2001)).

In general, a thermoelectric direct conversion device of this type includes a combination of a p-type and an n-type thermoelectric direct conversion semiconductor (thermoelectric conversion element) and utilizes a thermoelectric effect, such as the Thomson effect, the Peltier effect, or the Seebeck effect. FIG. 13 illustrates a typical thermoelectric direct conversion device. In this conventional thermoelectric direct conversion device 1, p-type thermoelectric direct conversion semiconductor chips (p-type semiconductors) 2 and n-type thermoelectric direct conversion semiconductor chips (n-type semiconductors) 3 are disposed between high-temperature electrodes 5 on a high-temperature insulating plate 7 and low-temperature electrodes 6 on a low-temperature insulating plate 8. A p-type thermoelectric direct conversion semiconductor chip 2 and an n-type thermoelectric direct conversion semiconductor chip 3 constitute a thermoelectric direct conversion semiconductor pair (semiconductor pair) 4. A large number of thermoelectric direct conversion semiconductor pairs are electrically and thermally connected to form the entire thermoelectric direct conversion device 1.

The p-type thermoelectric direct conversion semiconductor chips 2 and the n-type thermoelectric direct conversion semiconductor chips 3 are connected to the high-temperature electrodes 5 via high-temperature electrode-semiconductor chip junctions 11 and to the low-temperature electrodes 6 via low-temperature electrode-semiconductor chip junctions 12.

In the thermoelectric direct conversion device 1 having such a structure, a heat flow 13 is supplied to the high-temperature electrodes 5, the heat is conducted as heat flows 14 to the p-type thermoelectric direct conversion semiconductor chips 2 and the n-type thermoelectric direct conversion semiconductor chips 3 through the high-temperature electrode-semiconductor chip junctions 11. Along the heat flows 14 running through the semiconductor chips 2 and 3, positive holes 16, which are semiconductive carriers, in the p-type thermoelectric direct conversion semiconductor chips 2 and electrons 17, which are also semiconductive carriers, in the n-type thermoelectric direct conversion semiconductor chips 3 move toward the low-temperature electrodes 6 through the low-temperature electrode-semiconductor chip junctions 12.

The heat flows 14 running through the semiconductor chips 2 and 3 are discharged from the low-temperature electrodes 6 as a heat flow 15. When an electrical load 19 is electrically connected to the thermoelectric direct conversion device 1 via connectors 9 of the thermoelectric direct conversion device 1 and leads 10, the movement of the semiconductive carriers, that is, an electric current 18 can be taken out of the thermoelectric direct conversion device 1 and utilized.

In a manner as described above, a thermoelectric direct conversion device can directly convert the temperature difference between a high-temperature electrode and a low-temperature electrode into electricity by using thermoelectric direct conversion semiconductors, and send the electricity to the outside.

Alternatively, it is also possible to cause a heat flow from the low-temperature electrode to the high-temperature electrode or from the high-temperature electrode to the low-temperature electrode by applying an electric current from the outside (not shown).

In the case where heat is converted into electricity with the thermoelectric direct conversion device as described above, the conversion efficiency increases with a larger temperature difference between the high-temperature electrode and the low-temperature electrode. That is, when the high-temperature electrode has a higher temperature or the low-temperature electrode has a lower temperature, a high conversion efficiency can be attained.

For example, it is desirable to increase the temperature of the high-temperature electrode from a conventional level of 300° C. to at least 500° C. to improve the conversion efficiency. In the same manner, in the case where electricity is converted into heat with the thermoelectric direct conversion device, the temperature difference between the high-temperature electrode and the low-temperature electrode increases when the applied electric current is increased. However, when the thermoelectric direct conversion device shown in FIG. 13 is used in such a high-temperature atmosphere, a component through which the electric current flows, such as an electrode or a semiconductor chip, is liable to be degraded due to oxidation or nitriding, thus increasing the electrical resistance of the component. The increased electrical resistance impedes the electric current flow, thereby decreasing the conversion efficiency from heat to electricity or from electricity to heat over time. Thus, it may become difficult to maintain excellent conversion efficiency for a long period of time. Furthermore, when the oxidation or the nitriding of the components, such as the electrode or the semiconductor chip, proceeds, the surface and even the interior thereof may be oxidized or nitrided to cause chipping or cracking in the component and interrupt the electric current, thus decreasing the conversion efficiency from heat to electricity or from electricity to heat with time. It may therefore be difficult to maintain excellent conversion efficiency for a long period of time.

To prevent the oxidative degradation of components, the thermoelectric direct conversion device shown in FIG. 13 may be encapsulated in a metal case or a ceramic case and thereby isolated from the atmosphere.

However, there is another problem. That is, a chemical element in a high-temperature electrode 5 or a low-temperature electrode 6 may diffuse into a thermoelectric direct conversion semiconductor pair 4 and cause deterioration in the thermoelectric direct conversion performance of the thermoelectric direct conversion semiconductor pair 4 and the power generation performance of the thermoelectric direct conversion device 1.

Inversely, a chemical element in the thermoelectric direct conversion semiconductor pair 4 may diffuse into the high-temperature electrode 5 and the low-temperature electrode 6, thus causing deterioration in the mechanical characteristics or the electrical characteristics of the high-temperature electrode 5 and the low-temperature electrode 6.

### SUMMARY OF THE INVENTION

The present invention was accomplished to solve the above-mentioned problems. It is an object of the present invention to provide a thermoelectric direct conversion device in which the diffusion through a boundary between a thermoelectric direct conversion semiconductor and an electrode is prevented to maintain excellent power generation performance.

To solve the problems described above, a thermoelectric direct conversion device according to the present invention comprises:

a plurality of thermoelectric direct conversion semiconductor pairs each including a p-type semiconductor and an n-type semiconductor;

a plurality of high-temperature electrodes each electrically connecting the p-type semiconductor and the n-type semiconductor on a high-temperature side of each thermoelectric direct conversion semiconductor pair;

a high-temperature insulating plate thermally connected to the plurality of thermoelectric direct conversion semiconductor pairs via the plurality of high-temperature electrodes;

a plurality of low-temperature electrodes each electrically connecting the p-type semiconductor and the n-type semiconductor on a low-temperature side of each individual thermoelectric direct conversion semiconductor pair;

a low-temperature insulating plate thermally connected to the plurality of thermoelectric direct conversion semiconductor pairs via the plurality of low-temperature electrodes;

a diffusion barrier layer disposed between at least one of the high-temperature and low-temperature electrodes and at least one of the p-type semiconductor and n-type semiconductor of each thermoelectric direct conversion semiconductor pair; and

an airtight case formed by including a metal cover and a metal frame, or an integrated component of the metal cover and the metal frame, and the low-temperature insulating plate; wherein the metal cover is disposed to cover the high-temperature insulating plate, the metal frame is disposed to surround components including the plurality of thermoelectric direct conversion semiconductor pairs, the plurality of high-temperature electrodes and the plurality of low-temperature electrodes, and the airtight case is formed so as to isolate the plurality of thermoelectric direct conversion semiconductor pairs from an environmental atmosphere and an interior thereof to be placed in vacuum or in an inert gas.

In the thermoelectric direct conversion device according to the present invention, the diffusion through a boundary between a thermoelectric direct conversion semiconductor and an electrode is prevented and excellent power generation performance is maintained.

### BRIEF DESCRIPTION OF THE DRAWINGS

FIG. 1A is a schematic perspective view of a thermoelectric direct conversion device according to a first embodiment of the present invention, FIG. 1B is a schematic cross-sectional view taken along the line B-B, and FIG. 1C is a schematic view of a thermoelectric direct conversion semiconductor pair shown in FIG. 1B;

FIGS. 2A to 12A are cross-sectional views of second to twelfth embodiments, respectively, of the thermoelectric direct conversion device according to the present invention, and FIGS. 2B to 12B are schematic views for illustration of thermalelectric direct conversion semiconductor pairs or semiconducter chips, shown in FIGS. 2A to 12A, respectively; and,

FIG. 13 is a schematic perspective view of a conventional thermoelectric direct conversion device with an enlarged view of a principal part thereof.

### DESCRIPTION OF THE PREFERRED EMBODIMENTS

Embodiments of the thermoelectric direct conversion device according to the present invention will be described below with reference to the accompanying drawings, wherein like parts are denoted by like reference numerals.

### (1) Structure of Thermoelectric Direct Conversion Device According to a First Embodiment

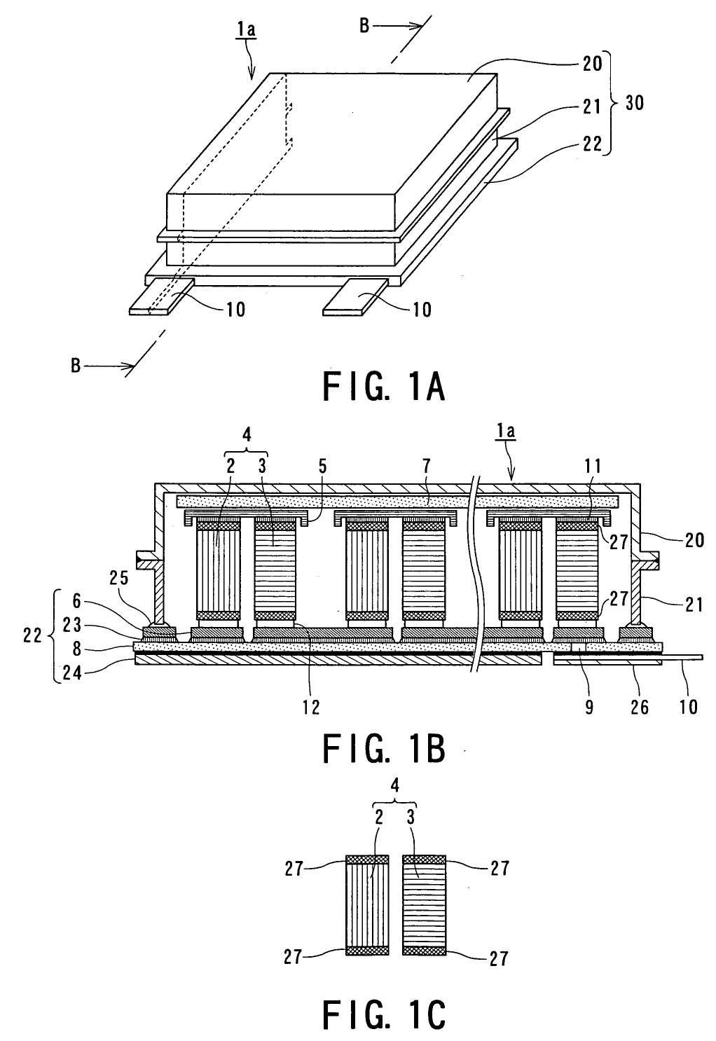

FIG. 1 illustrates a thermoelectric direct conversion device according to a first embodiment of the present invention.

FIG. 1A is a schematic perspective view of a thermoelectric direct conversion device 1a according to the first embodiment of the present invention. FIG. 1B is a schematic cross-sectional view of the thermoelectric direct conversion device 1a, taken along the line B-B in FIG. 1A. FIG. 1C is a schematic view of a thermoelectric direct conversion semiconductor pair 4 shown in the thermoelectric direct conversion device 1a.

As shown in FIG. 1, the thermoelectric direct conversion device 1a includes a plurality of thermoelectric direct conversion semiconductor pairs 4 for directly converting thermal energy to electrical energy or electrical energy to thermal energy, and an airtight case 30 for isolating the thermoelectric direct conversion semiconductor pairs 4 from the environmental atmosphere.

An airtight case 30 is composed of a metal cover 20, a metal frame 21, and a low-temperature substrate 22. The metal cover 20 covers a high-temperature insulating plate 7 thermally connected to high-temperature ends of a plurality of thermoelectric direct conversion semiconductor pairs 4. The metal frame 21 surrounds the plurality of thermoelectric direct conversion semiconductor pairs 4. The low-temperature substrate 22 is thermally connected to low-temperature ends of the plurality of thermoelectric direct conversion semiconductor pairs 4. The airtight case 30 isolates the interior including the plurality of thermoelectric direct-conversion semiconductor pairs 4 from the atmosphere. The interior of the airtight case 30 may be placed in vacuum or in an inert gas atmosphere.

Preferably, the inert gas is selected from the group consisting of nitrogen, helium, neon, argon, krypton, and xenon. The inert gas can also be a mixture of these gases. By forming an inert or non-oxidizing atmosphere of vacuum or such inert gases in the airtight case 30, it becomes possible to effectively prevents the semiconductor chips and other components from deteriorating due to oxidation and other reactions. Thus, the thermoelectric direct conversion device 1a can maintain high conversion efficiency for a long period of time.

Preferably, the inert gas in the airtight case 30 has a pressure lower than the environmental air pressure at room temperature. This reduced internal pressure prevents the breakage of the airtight case 30 due to the increase in the internal pressure at high temperatures. This also prevents moisture from remaining in the airtight case 30, thus suppressing the deterioration of the semiconductor chips due to the moisture. Furthermore, the reduced internal pressure is also effective for decreasing the thermal conductivity in the airtight case 30, thereby suppressing heat dissipation from the semiconductor chips to the metal frame and improving the thermoelectric conversion efficiency.

The metal cover 20 and the metal frame 21 of the airtight case 30 may be made of a heat-resistant alloy, such as a nickel-based alloy, or a heat-resistant metal. Preferably, the heat-resistant alloy or the heat-resistant metal forming the metal cover 20 and the metal frame 21 are selected from the group consisting of a nickel-based alloy, nickel, carbon steel, stainless steel, an iron-based alloy containing chromium, an iron-based alloy containing silicon, an alloy containing cobalt, and an alloy containing nickel or copper, from the viewpoint of durability at high temperatures.

As shown in FIGS. 1B and 1C, each thermoelectric direct conversion semiconductor pair 4 is composed of a p-type semiconductor 2 and an n-type semiconductor 3.

Preferably, the p-type semiconductor 2 and the n-type semiconductor 3 are thermoelectric direct conversion semiconductors composed of at least three elements selected from the group consisting of rare earth elements, actinoids, cobalt, iron, rhodium, ruthenium, palladium, platinum, nickel, antimony, titanium, zirconium, hafnium, nickel, tin, silicon, manganese, zinc, boron, carbon, nitrogen, gallium, germanium, indium, vanadium, niobium, barium, and magnesium, from the viewpoints of thermoelectric conversion efficiency and thermoelectric effect for a long period of time.

In addition, it is preferred that p-type semiconductor 2 and the n-type semiconductor 3 have a crystal structure, in terms of a principal phase, selected from the group consisting of a skutterudite structure, a filled skutterudite structure, a Heusler structure, a half-Heusler structure, and a clathrate structure, or mixed phases of these, from the viewpoint of thermoelectric effect.

The high-temperature ends (the upper ends in FIG. 1B) of each thermoelectric direct conversion semiconductor pair 4 are disposed to contact a high-temperature electrode 5 via high-temperature electrode-semiconductor chip junctions 11. As a result, it becomes possible to absorb a stress possibly caused between the high-temperature electrode 5 and the high-temperature insulating plate 7 due to expansion of these members at elevated temperatures when they are bonded to each other, by allowing a slippage between them contacting each other.

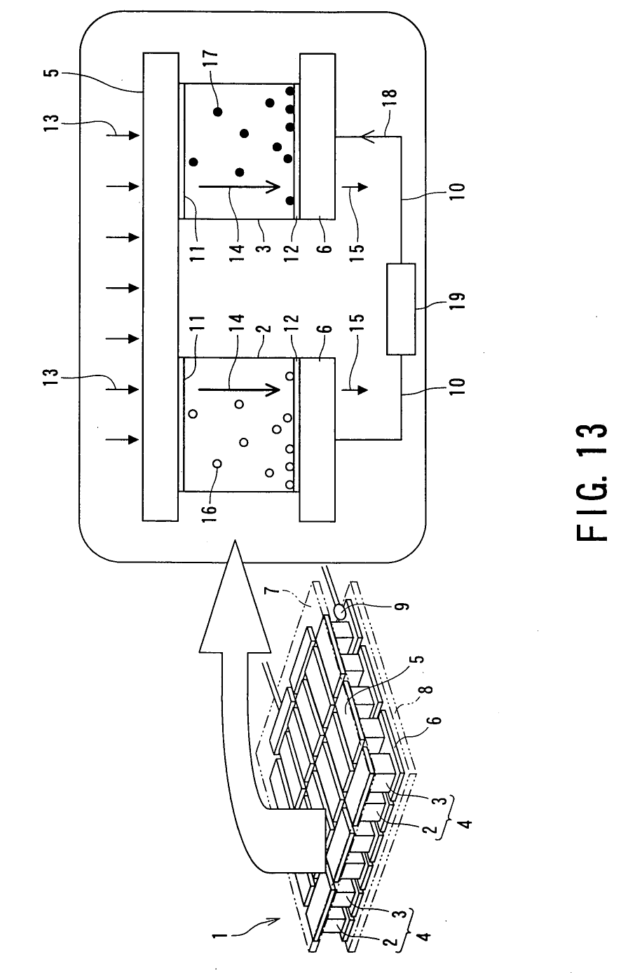

High-temperature electrodes 5 are separately placed in the form of patches on the high-temperature ends of all the thermoelectric direct conversion semiconductor pairs 4 (see FIG. 13), and are electrically isolated from neighboring high-temperature electrodes 5. The high-temperature electrodes 5 may be made of an electroconductive metal, for example, copper.

The high-temperature insulating plate 7 is disposed between the high-temperature electrodes 5 and the metal cover 20 to cover substantially all the plurality of thermoelectric direct conversion semiconductor pairs 4. The high-temperature insulating plate 7 may be a heat conductive insulating ceramic substrate, for example, an alumina (Al₂O₃) substrate.

The high-temperature insulating plate 7 is disposed in contact with the inner surface of the metal cover 20 and is thermally connected to the metal cover 20.

The low-temperature ends of the thermoelectric direct conversion semiconductor pairs 4 are thermally connected to the low-temperature substrate 22.

The low-temperature substrate 22 is composed to include low-temperature electrodes 6, a low-temperature insulating plate 8, and a radiator 24 for dissipating heat to a low-temperature system (not shown).

Each low-temperature electrode 6 electrically connects a p-type semiconductor 2 (or an n-type semiconductor 3) of a thermoelectric direct conversion semiconductor pair 4 and an n-type semiconductor 3 (or a p-type semiconductor 2) of the adjacent thermoelectric direct conversion semiconductor pair 4, via low-temperature electrode-semiconductor chip junctions 12 made of, for example, solder.

The low-temperature electrodes 6 are thermally connected to the low-temperature insulating plate 8 via low-temperature electrode-low-temperature insulating plate junctions 23.

The low-temperature substrate 22 may be formed by bonding metal plates onto both faces of the low-temperature insulating plate 8 made of ceramic. An upper metal plate on the low-temperature insulating plate 8 in FIG. 1B is formed into the low-temperature electrodes 6. A lower metal plate is disposed to function as the radiator 24 to a low-temperature system.

Such an integrated low-temperature substrate 22 can simplify the assembling of the thermoelectric direct conversion device 1a. In addition, the resultant high bonding strengths of the low-temperature electrodes 6 and the radiator 24 onto the low-temperature insulating plate 8 ensure high durability of the thermoelectric direct conversion device 1a.

Preferably, the metal plates forming the low-temperature electrodes 6 and the radiator 24 are made of at least one material selected from the group consisting of copper, silver, aluminum, tin, an iron-based alloy, nickel, a nickel-based alloy, titanium, and a titanium-based alloy, from the viewpoints of heat resistance and electroconductivity or thermal conductivity.

Preferably, the ceramic plate of the low-temperature insulating plate 8 is made of at least one material selected from the group consisting of alumina, ceramic containing alumina, a metal containing dispersed alumina powder, silicon nitride, ceramic containing silicon nitride, aluminum nitride, ceramic containing aluminum nitride, zirconia, ceramic containing zirconia, yttria, ceramic containing yttria, silica, ceramic containing silica, beryllia, and ceramic containing beryllia, from the viewpoint of stability of insulation resistance.

The metal cover 20 and the metal frame 21 may be welded or may be formed integrally with each other. The integral molding of the metal cover 20 and the metal frame 21 decreases the number of components and simplifies the assembly.

The method for bonding the metal frame 21 and the low-temperature substrate 22 is not limited to any particular method. Preferably, they are bonded by welding, soldering, brazing, or diffusion bonding, or with an adhesive, from the viewpoint of bonding strength.

When thermal energy is converted into electrical energy by the thermoelectric direct conversion device 1a having the structure described above, a high-temperature system (not shown) is thermally connected to the metal cover 20 of the thermoelectric direct conversion device 1a, and a low-temperature system (not shown) is thermally connected to the radiator 24.

As a result, heat flows are generated from the high-temperature ends to the low-temperature ends in the thermoelectric direct conversion semiconductor pairs 4, thereby causing flows of positive holes and electrons in the thermoelectric direct conversion semiconductor pairs 4 to generate an electric current. The total of the electric current through the thermoelectric direct conversion semiconductor pairs 4 can be taken out from leads 10 and supplied to an external load.

The thermoelectric conversion efficiency can be increased if the temperature difference between the high-temperature system and the low-temperature system is increased. For example, when the low-temperature system is at room temperature, a higher thermoelectric conversion efficiency can be attained at a higher temperature of the high-temperature system.

Thus, the thermoelectric conversion efficiency can be effectively increased when the metal cover 20 of the thermoelectric direct conversion device 1a is operated at a higher temperature, for example, 500° C.

However, when the thermoelectric direct conversion device 1a is operated at a high temperature in the atmospheric environment, the components, including the electrodes and the semiconductor chips, may easily deteriorate by oxidation or nitriding. In order to prevent the deterioration of the components and maintain high conversion efficiency from heat to electricity or electricity to heat for a long period of time, it is effective to use an airtight case 30 to isolate the thermoelectric direct conversion device 1a from the atmosphere, as shown in the present embodiment.

In the present embodiment, the metal cover 20, the metal frame 21, and the low-temperature substrate 22 are integrally bonded to each other to form the airtight case 30 that the interior components are encapsulated or sealed up within a non-oxidizing gas, such as nitrogen. The metal cover 20 and the part of the metal frame 21 in the vicinity of the metal cover 20 is caused to have a high temperature of, for example, 500° C. or higher. Thus, an organic material, such as an acrylic resin or a material containing an organic compound, cannot form a metal cover 20 and a metal frame 21 because of its low melting point or low boiling point. On the other hand, a metal for use in the metal cover 20 and the metal frame 21 has a melting point or a boiling point well in excess of, for example, at least 500° C. and can maintain the airtightness at high temperatures. The use of inorganic material, such as alumina, is also not appropriate because of its porosity to maintain the airtightness at a high temperature, for example, of 500° C. Furthermore, because such an inorganic material has a thermal expansion coefficient smaller than that of a metal, it cannot follow a transient temperature change, such as thermal shock during operation, and may therefore be broken. Thus, an airtight case 30 made an inorganic material has low reliability. In contrast, the metal for use in the metal cover 20 and the metal frame 21 may have a thermal expansion coefficient of 10 to 20×10⁻⁶/K, which is almost the same as that of the semiconductor chips enclosed therein. Thus, the metal cover 20 and the metal frame 21 can form and reliably retain an airtight case 30.

As shown in FIG. 1, also the leads 10 for supplying the generated electric power to the external load are securely connected to low-temperature electrodes 6 with connectors 9 in the low-temperature insulating plate 8, so that the airtight case 30 can maintain airtightness.

In the thermoelectric direct conversion device 1a according to the present embodiment, the airtight case 30 containing the thermoelectric direct conversion semiconductor pairs 4, the high-temperature electrodes 5 and the low-temperature electrodes 6 is hermetically sealed and can be maintained under vacuum or in an inert gas atmosphere. As a result, it becomes possible to effectively prevent the components in the airtight case 30 of the thermoelectric direct conversion device 1a from deteriorating by oxidation, nitriding, and other reactions.

### (2) Diffusion Barrier Layer

As shown in FIGS. 1B and 1C, the thermoelectric direct conversion device 1a according to the first embodiment includes diffusion barrier layers 27 between the thermoelectric direct conversion semiconductor pairs 4 and the high-temperature electrodes 5 and between the thermoelectric direct conversion semiconductor pairs 4 and the low-temperature electrodes 6.

When a thermoelectric direct conversion semiconductor pair 4 and a high-temperature electrode 5 are directly bonded to each other, substances forming the thermoelectric direct conversion semiconductor pair 4 and the high-temperature electrode 5 can mutually diffuse from one to the other, while it may depend on the combination of the substances.

In particular, the diffusion is liable to occur when the thermoelectric direct conversion device 1a is operated at high temperatures for a long period of time.

For example, copper as a substance forming the high-temperature electrode 5 can diffuse into the thermoelectric direct conversion semiconductor pair 4 to cause deterioration in the thermoelectric conversion performance of the thermoelectric direct conversion semiconductor pair 4. This results in poor power generation performance of the thermoelectric direct conversion device 1a.

To the contrary, a substance forming the thermoelectric direct conversion semiconductor pair 4 can diffuse into the high-temperature electrode 5 to cause deterioration in the electrical characteristics or the mechanical characteristics of the high-temperature electrode 5 in some case.

The diffusion can occur not only between the thermoelectric direct conversion semiconductor pair 4 and the high-temperature electrode 5, but also between the thermoelectric direct conversion semiconductor pair 4 and the low-temperature electrode 6.

In the thermoelectric direct conversion device 1a according to the first embodiment, the diffusion barrier layers 27 are placed between the thermoelectric direct conversion semiconductor pairs 4 and the high-temperature electrodes 5 and between the thermoelectric direct conversion semiconductor pairs 4 and the low-temperature electrodes 6, to prevent diffusion, thereby increasing the durability and the reliability of the thermoelectric direct conversion device 1a.

The diffusion barrier layers 27 may be formed of an electrically conductive substance that has a melting point of at least 500° C. and that comprises a simple substance of an element selected from the group consisting of tungsten, molybdenum, tantalum, platinum, gold, silver, copper, rhodium, ruthenium, palladium, vanadium, chromium, aluminum, manganese, silicon, germanium, silicon, nickel, niobium, iridium, hafnium, titanium, zirconium, cobalt, zinc, tin, antimony, boron, carbon, and nitrogen; a compound composed of at least two of these elements; a mixture containing at least two of these elements; a mixture containing at least two of the compounds; and a mixture containing at least two of the simple substances, the compounds, and the mixtures.

The diffusion barrier layers 27 may be formed of at least one substance selected from the group consisting of (a) a layered complex oxide composed of cobalt and one substance selected from the group consisting of copper oxide, carbon, boron, sodium, and calcium, (b) aluminum nitride, (c) uranium nitride, (d) silicon nitride, (e) molybdenum disulfide, (f) a thermoelectric conversion material containing a cobalt antimonide compound having a skutterudite crystal structure as the principal phase, (g) a thermoelectric conversion material containing a clathrate compound as the principal phase, and (h) a thermoelectric conversion material containing a half-Heusler compound as the principal phase; a compound composed of at least two of the substances (a) to (h); a mixture containing at least two of the substances (a) to (h); and a solid solution composed of at least two of the substances (a) to (h).

The half-Heusler compound may be a thermoelectric direct conversion semiconductor substance containing at least one element selected from the group consisting of titanium, zirconium, hafnium, nickel, tin, cobalt, antimony, vanadium, chromium, niobium, tantalum, molybdenum, palladium, and rare earth elements.

The diffusion barrier layers 27 may be formed on the thermoelectric direct conversion semiconductor pairs 4 by plating or sputtering.

To increase the productivity or reduce the processing cost, the diffusion barrier layers 27 may also be formed on the thermoelectric direct conversion semiconductor pairs 4 by spraying or brushing.

In the thermoelectric direct conversion device 1a according to the first embodiment, the diffusion barrier layers 27 disposed between the thermoelectric direct conversion semiconductor pairs 4 and the high-temperature electrodes 5 and between the thermoelectric direct conversion semiconductor pairs 4 and the low-temperature electrodes 6 prevent the diffusion of substance forming the thermoelectric direct conversion semiconductor pairs 4 into the electrodes 5 and 6, and the diffusion of a substance forming the electrodes 5 and 6 into the thermoelectric direct conversion semiconductor pairs 4. Thus, the thermoelectric direct conversion device 1a can maintain excellent power generation performance.

### (3) Structures of Thermoelectric Direct Conversion Devices According to Second to Ninth Embodiments

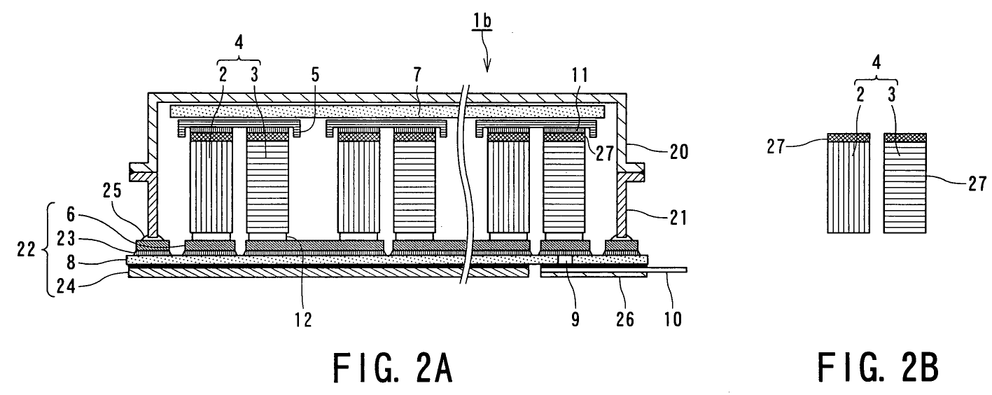

FIG. 2A is a cross-sectional view of a thermoelectric direct conversion device 1b according to a second embodiment of the present invention, and FIG. 2B is a schematic view of a thermoelectric direct conversion semiconductor pair 4 shown in FIG. 2A.

The thermoelectric direct conversion device 1b according to the second embodiment includes diffusion barrier layers 27 only between thermoelectric direct conversion semiconductor pairs 4 and high-temperature electrodes 5.

The thermoelectric direct conversion device 1b converts heat into electricity on the basis of a temperature difference. Thus, even when the interior of the thermoelectric direct conversion device 1b is at a high temperature, the contact surfaces between the low-temperature electrodes 6 and the thermoelectric direct conversion semiconductor pairs 4 can be kept at a low temperature. Under such a condition, it is possible that the diffusion of an element occurs only through the contact surfaces between the high-temperature electrodes 5 and the thermoelectric direct conversion semiconductor pairs 4, but does not occur through the contact surfaces between the low-temperature electrodes 6 and the thermoelectric direct conversion semiconductor pairs 4, while it may depend on a certain combination of the material of the electrodes 5 and 6 and the material of the thermoelectric direct conversion semiconductor pairs 4.

In such a case, diffusion barrier layers 27 can be omitted from a boundary not causing the diffusion between the low-temperature electrodes 6 and the thermoelectric direct conversion semiconductor pairs 4.

In addition to the effects in the first embodiment, the thermoelectric direct conversion device 1b according to the second embodiment having the diffusion barrier layers 27 only between the high-temperature electrodes 5 and the thermoelectric direct conversion semiconductor pairs 4 can reduce the cost associated with the diffusion barrier layers 27 to a half of that in the first embodiment.

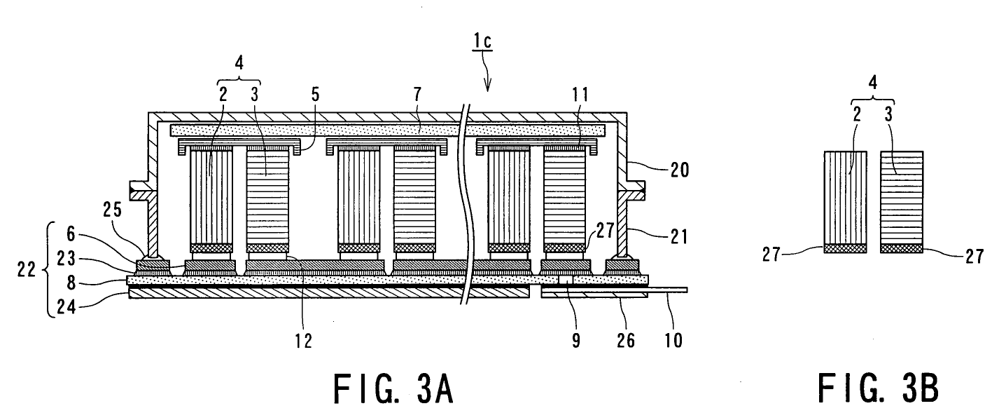

FIG. 3A is a cross-sectional view of a thermoelectric direct conversion device 1c according to a third embodiment of the present invention, and FIG. 3B is a schematic view of a thermoelectric direct conversion semiconductor pair 4 shown in FIG. 3A.

The thermoelectric direct conversion device 1c according to the third embodiment includes diffusion barrier layers 27 only between thermoelectric direct conversion semiconductor pairs 4 and low-temperature electrodes 5.

With a certain combination of the material of the electrodes 5 and 6 and the material of the thermoelectric direct conversion semiconductor pairs 4, the diffusion may not occur even under high temperature conditions.

On the other hand, the diffusion can occur between the low-temperature electrodes 6 and the low-temperature electrode-semiconductor chip junctions 12 even when the low-temperature electrodes 6 are maintained at a low temperature. For example, substances can diffuse between solder of the low-temperature electrode-semiconductor chip junctions 12 and the low-temperature electrodes 6. Under such a condition, the diffusion can be prevented by placing the diffusion barrier layers 27 only between the thermoelectric direct conversion semiconductor pairs 4 and the low-temperature electrodes 6.

In addition to the effects in the first embodiment, the thermoelectric direct conversion device 1c according to the third embodiment having the diffusion barrier layers 27 only between the low-temperature electrodes 6 and the thermoelectric direct conversion semiconductor pairs 4 can reduce the cost associated with the diffusion barrier layers 27 to a half of that in the first embodiment.

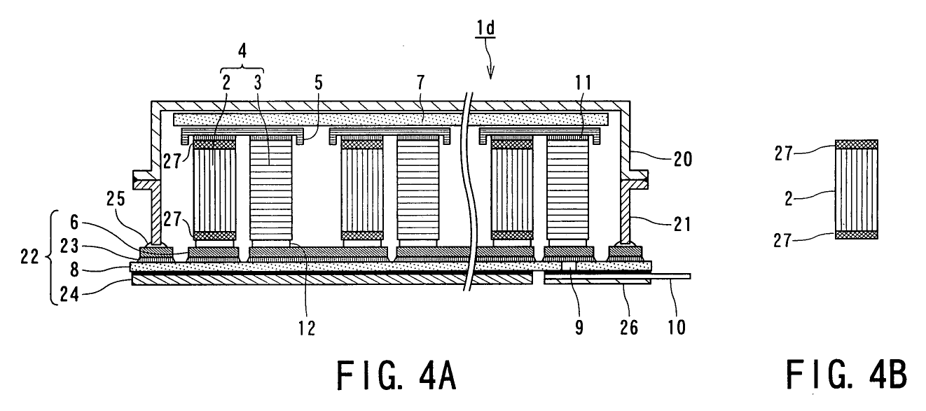

FIG. 4A is a cross-sectional view of a thermoelectric direct conversion device 1d according to a fourth embodiment of the present invention, and FIG. 4B is a schematic view of a p-type semiconductor 2 shown in FIG. 4A.

In the thermoelectric direct conversion device 1d according to the fourth embodiment, diffusion barrier layers 27 are provided only for p-type semiconductors 2 of thermoelectric direct conversion semiconductor pairs 4.

With a certain combination of the material of electrodes 5 and 6 and the material of the thermoelectric direct conversion semiconductor pairs 4, the diffusion of an element may not occur even under high temperature conditions. Furthermore, the material of the p-type semiconductors 2 may be different from the material of the n-type semiconductors 3. Thus, it is possible that the diffusion occurs between the p-type semiconductors 2 and the electrodes 5 and 6, whereas it does not occur between the n-type semiconductors 3 and the electrodes 5 and 6.

In such a case, the diffusion barrier layers 27 may be placed only between the p-type semiconductors 2 and the electrodes 5 and 6.

In addition to the effects in the first embodiment, the thermoelectric direct conversion device 1d according to the fourth embodiment having the diffusion barrier layers 27 provided only for the p-type semiconductors 2 can reduce the cost associated with the diffusion barrier layers 27 to a half of that in the first embodiment.

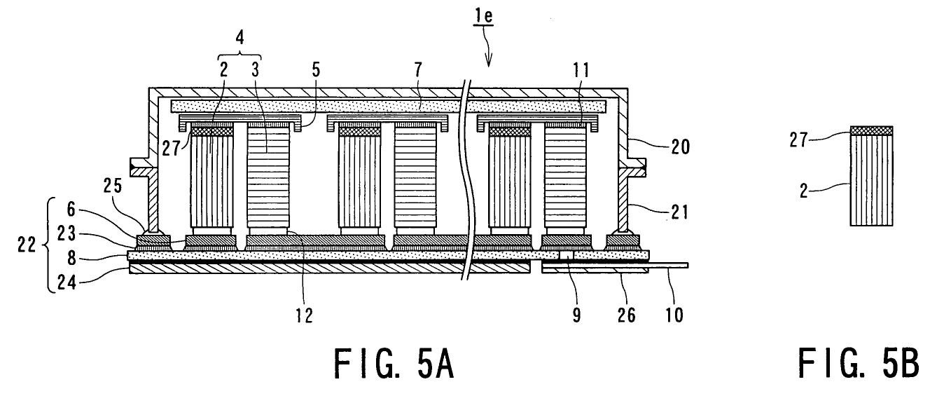

FIG. 5A is a cross-sectional view of a thermoelectric direct conversion device 1e according to a fifth embodiment of the present invention, and FIG. 5B is a schematic view of a p-type semiconductor 2 shown in FIG. 5A.

The fifth embodiment is a combination of the fourth embodiment and the second embodiment. That is, diffusion barrier layers 27 are placed only between p-type semiconductors 2 and high-temperature electrodes 5. This embodiment is effective when the diffusion does not occur in n-type semiconductors 3 or between the p-type semiconductors 2 and low-temperature electrodes 6.

In addition to the effects in the first embodiment, the thermoelectric direct conversion device 1e according to the fifth embodiment having the diffusion barrier layers 27 only between the p-type semiconductors 2 and the high-temperature electrodes 5 can reduce the cost associated with the diffusion barrier layers 27 to a quarter of that in the first embodiment.

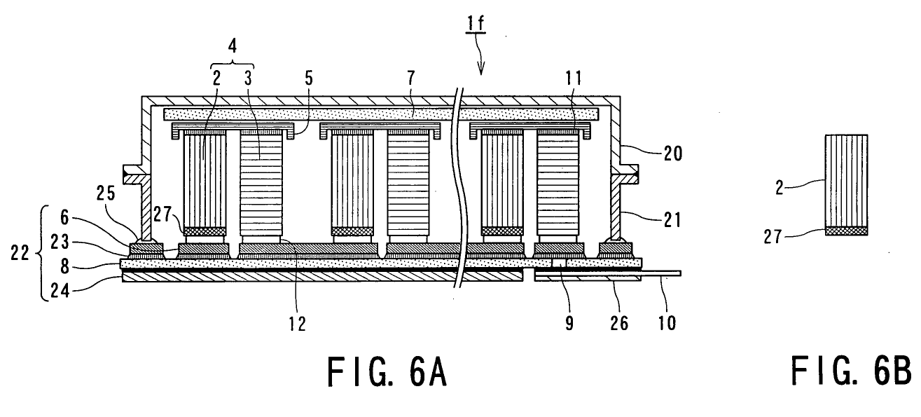

FIG. 6A is a cross-sectional view of a thermoelectric direct conversion device if according to a sixth embodiment of the present invention, and FIG. 6B is a schematic view of a p-type semiconductor 2 shown in FIG. 6A.

The sixth embodiment is an integration of the fourth embodiment and the third embodiment. That is, diffusion barrier layers 27 are placed only between p-type semiconductors 2 and low-temperature electrodes 6. This embodiment is effective when the diffusion of an element does not occur in n-type semiconductors 3 or between the p-type semiconductors 2 and high-temperature electrodes 5.

In addition to the effects in the first embodiment, the thermoelectric direct conversion device 1f according to the sixth embodiment having the diffusion barrier layers 27 only between the p-type semiconductors 2 and the low-temperature electrodes 6 can reduce the cost associated with the diffusion barrier layers 27 to a quarter of that in the first embodiment.

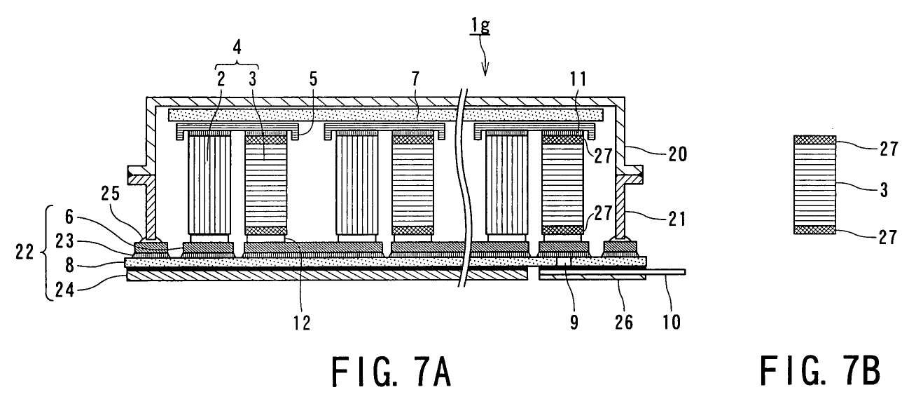

FIG. 7A is a cross-sectional view of a thermoelectric direct conversion device 1g according to a seventh embodiment of the present invention, and FIG. 7B is a schematic view of an n-type semiconductor 3 shown in FIG. 7A.

In the thermoelectric direct conversion device 1g according to the seventh embodiment, diffusion barrier layers 27 are provided only for n-type semiconductors 3 of thermoelectric direct conversion semiconductor pairs 4.

This embodiment is effective in case where the diffusion of an element occurs between the n-type semiconductors 3 and electrodes 5 and 6, but does not occur between p-type semiconductors 2 and the electrodes 5 and 6.

In addition to the effects in the first embodiment, the thermoelectric direct conversion device 1g according to the seventh embodiment having the diffusion barrier layers 27 provided only for the n-type semiconductors 3 can reduce the cost associated with the diffusion barrier layers 27 to a half of that in the first embodiment.

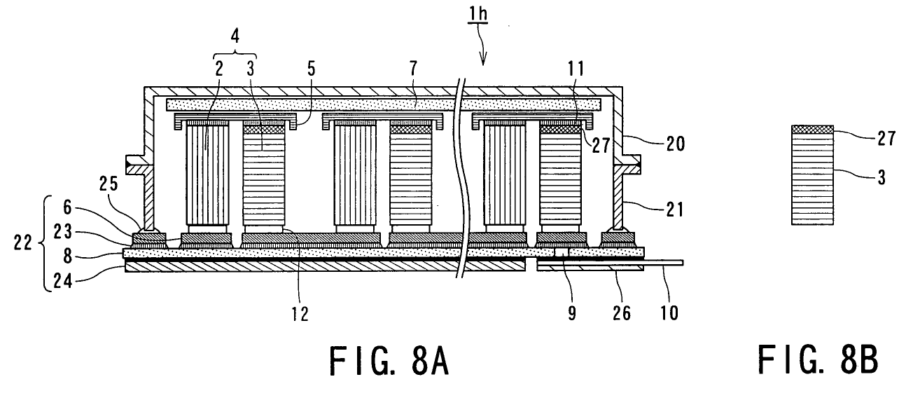

FIG. 8A is a cross-sectional view of a thermoelectric direct conversion device 1h according to an eighth embodiment of the present invention, and FIG. 8B is a schematic view of an n-type semiconductor 3 shown in FIG. 8A.

The eighth embodiment is a combination of the seventh embodiment and the second embodiment. That is, diffusion barrier layers 27 are placed only between n-type semiconductors 3 and high-temperature electrodes 5. This embodiment is effective when the diffusion of an element does not occur in p-type semiconductors 2 or between the n-type semiconductors 3 and low-temperature electrodes 6.

In addition to the effects in the first embodiment, the thermoelectric direct conversion device 1h according to the eighth embodiment having the diffusion barrier layers 27 only between the n-type semiconductors 3 and the high-temperature electrodes 5 can reduce the cost associated with the diffusion barrier layers 27 to a quarter of that in the first embodiment.

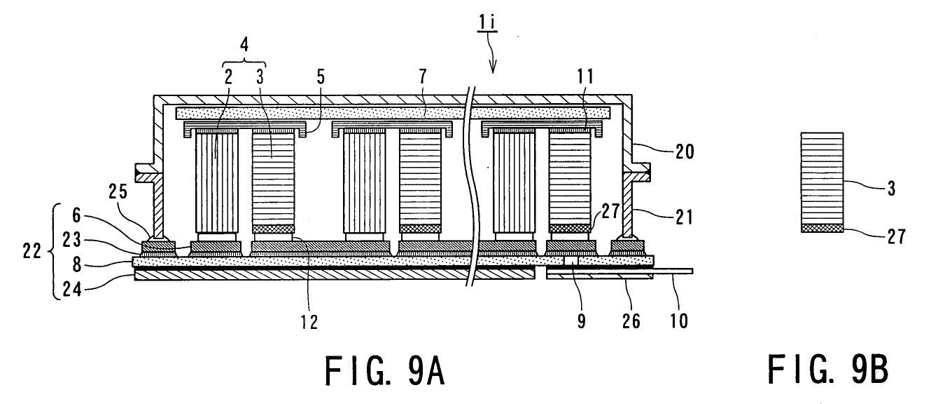

FIG. 9A is a cross-sectional view of a thermoelectric direct conversion device 1i according to a ninth embodiment of the present invention, and FIG. 9B is a schematic view of an n-type semiconductor 3 shown in FIG. 9A.

The ninth embodiment is a combination of the seventh embodiment and the third embodiment. That is, diffusion barrier layers 27 are placed only between n-type semiconductors 3 and low-temperature electrodes 6. This embodiment is effective when the diffusion of an element does not occur in p-type semiconductors 2 or between the n-type semiconductors 3 and high-temperature electrodes 5.

In addition to the effects in the first embodiment, the thermoelectric direct conversion device 1i according to the ninth embodiment having the diffusion barrier layers 27 only between the n-type semiconductors 3 and the low-temperature electrodes 6 can reduce the cost associated with the diffusion barrier layers 27 to a quarter of that in the first embodiment.

### (4) Structures of Thermoelectric Direct Conversion Devices According to Tenth to Twelfth Embodiments

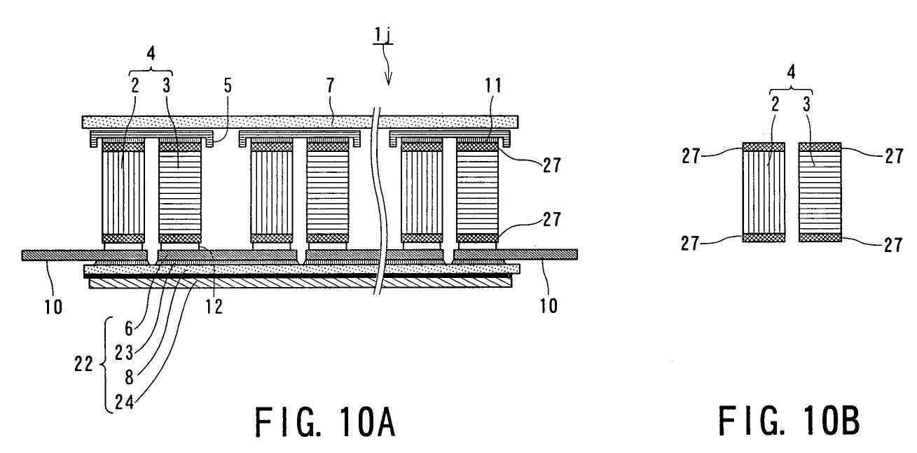

FIG. 10A is a cross-sectional view of a thermoelectric direct conversion device 1j according to a tenth embodiment of the present invention, and FIG. 10B is a schematic view of a thermoelectric direct conversion semiconductor pair 4 shown in FIG. 10A.

A first difference between the thermoelectric direct conversion device 1j according to the tenth embodiment and the thermoelectric direct conversion device 1a according to the first embodiment is that the thermoelectric direct conversion device 1j does not include a metal cover 20 or a metal frame 21 of an airtight case 30.

A second difference between the thermoelectric direct conversion device 1j according to the tenth embodiment and the thermoelectric direct conversion device 1a according to the first embodiment is that the leads 10 of these embodiments have different structures.

The tenth embodiment is based on an assumption that a plurality of thermoelectric direct conversion devices 1j are connected to each other in series or in parallel and are entirely placed in an inert gas atmosphere.

Thus, the plurality of thermoelectric direct conversion devices 1j do not individually require a airtight case 30, or a metal cover 20 and a metal frame 21. This reduces the weight of the thermoelectric direct conversion devices 1j.

To enhance the serial or parallel connection of the thermoelectric direct conversion devices 1j, low-temperature electrodes 6 at both ends of each thermoelectric direct conversion device 1j are extended to form leads 10.

There is no difference between the tenth embodiment and the first embodiment in the other respects.

In the tenth embodiment, as in the first embodiment, the diffusion barrier layers 27 disposed between thermoelectric direct conversion semiconductor pairs 4 and high-temperature electrodes 5 and between the thermoelectric direct conversion semiconductor pairs 4 and the low-temperature electrodes 6 prevent a substance forming the thermoelectric direct conversion semiconductor pairs 4 from diffusing into the electrodes 5 and 6, and a substance forming the electrodes 5 and 6 from diffusing into the thermoelectric direct conversion semiconductor pairs 4. Thus, the thermoelectric direct conversion device 1j can maintain excellent power generation performances.

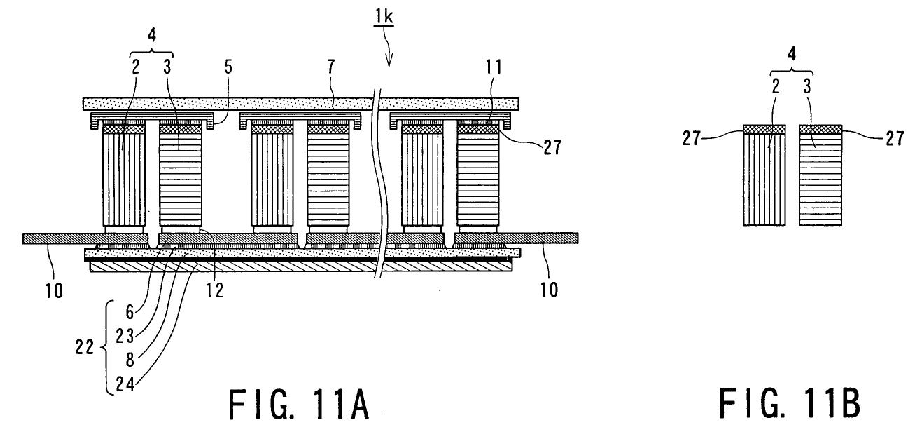

FIG. 11A is a cross-sectional view of a thermoelectric direct conversion device 1k according to an eleventh embodiment of the present invention, and FIG. 11B is a schematic view of a thermoelectric direct conversion semiconductor pair 4 shown in FIG. 11A.

The eleventh embodiment is a combination of the tenth embodiment and the second embodiment. That is, diffusion barrier layers 27 are placed only between thermoelectric direct conversion semiconductor pairs 4 and high-temperature electrodes 5. This embodiment is effective when the diffusion of an element does not occur between the thermoelectric direct conversion semiconductor pairs 4 and low-temperature electrodes 6.

In addition to the effects in the tenth embodiment, the thermoelectric direct conversion device 1k according to the eleventh embodiment having the diffusion barrier layers 27 only between the thermoelectric direct conversion semiconductor pairs 4 and the high-temperature electrodes 5 can reduce the cost associated with the diffusion barrier layers 27 to a half of that in the tenth embodiment.

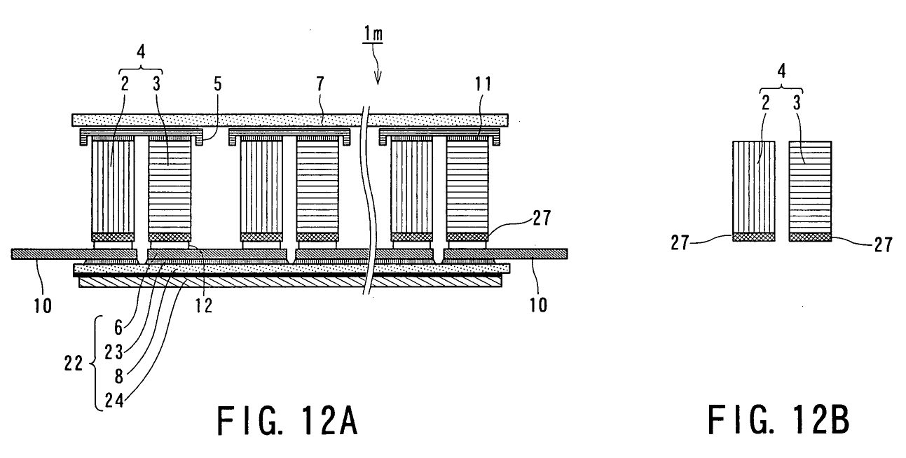

FIG. 12A is a cross-sectional view of a thermoelectric direct conversion device 1m according to a twelfth embodiment of the present invention, and FIG. 12B is a schematic view of a thermoelectric direct conversion semiconductor pair 4 shown in FIG. 12A.

The twelfth embodiment is a combination of the tenth embodiment and the third embodiment. That is, diffusion barrier layers 27 are placed only between thermoelectric direct conversion semiconductor pairs 4 and low-temperature electrodes 6. This embodiment is effective when the diffusion of an element does not occur between the thermoelectric direct conversion semiconductor pairs 4 and high-temperature electrodes 5.

In addition to the effects in the tenth embodiment, the thermoelectric direct conversion device 1m according to the twelfth embodiment having the diffusion barrier layers 27 only between the thermoelectric direct conversion semiconductor pairs 4 and the low-temperature electrodes 6 can reduce the cost associated with the diffusion barrier layers 27 to a half of that in the tenth embodiment.

As further modifications of the tenth embodiment to the twelfth embodiment, diffusion barrier layers 27 can be provided only for either p-type semiconductors 2 or n-type semiconductors 3 of thermoelectric direct conversion semiconductor pairs 4.

Incidentally, in the first embodiment to the twelfth embodiment, the diffusion barrier layers 27 are formed on the thermoelectric direct conversion semiconductor pairs 4. However, it is also possible to form the diffusion barrier layers 27 on the high-temperature electrodes 5 and/or the low-temperature electrodes 6. These modifications can also prevent the diffusion between the thermoelectric direct conversion semiconductor pairs 4 and the electrodes 5 and 6, thus achieving similar effects as in the first to twelfth embodiments.

What is claimed is:

1. A thermoelectric direct conversion device comprising:
a plurality of thermoelectric direct conversion semiconductor pairs each including a p-type semiconductor and an n-type semiconductor;
a plurality of high-temperature electrodes each electrically connecting the p-type semiconductor and the n-type semiconductor on a high-temperature side of each thermoelectric direct conversion semiconductor pair;
a high-temperature insulating plate thermally connected to the plurality of thermoelectric direct conversion semiconductor pairs via the plurality of high-temperature electrodes;
a plurality of low-temperature electrodes each electrically connecting the p-type semiconductor and the n-type semiconductor on a low-temperature side of each individual thermoelectric direct conversion semiconductor pair;
a low-temperature insulating plate thermally connected to the plurality of thermoelectric direct conversion semiconductor pairs via the plurality of low-temperature electrodes;
a diffusion barrier layer disposed between at least one of the high-temperature and low-temperature electrodes and at least one of the p-type semiconductor and n-type semiconductor of each thermoelectric direct conversion semiconductor pair; and
an airtight case formed by including a metal cover and a metal frame, or an integrated component of the metal cover and the metal frame, and the low-temperature insulating plate; wherein the metal cover is disposed to cover the high-temperature insulating plate, the metal frame is disposed to surround components including the plurality of thermoelectric direct conversion semiconductor pairs, the plurality of high-temperature electrodes and the plurality of low-temperature electrodes, and the airtight case is formed so as to isolate the plurality of thermoelectric direct conversion semiconductor pairs from an environmental atmosphere and to place an interior thereof in vacuum or in an inert gas.

2. The thermoelectric direct conversion device according to claim 1, wherein the diffusion barrier layer is a film formed on each thermoelectric direct conversion semiconductor pair by plating or sputtering.

3. The thermoelectric direct conversion device according to claim 1, wherein the diffusion barrier layer is formed of an electrically conductive substance that has a melting point of at least 500° C. and that comprises a simple substance of an element selected from the group consisting of tungsten, molybdenum, tantalum, platinum, gold, silver, copper, rhodium, ruthenium, palladium, vanadium, chromium, aluminum, manganese, silicon, germanium, nickel, niobium, iridium, hafnium, titanium, zirconium, cobalt, zinc, tin, antimony, boron, carbon, and nitrogen; a compound composed of at least two of the elements; a mixture containing at least two of the elements; a mixture containing at least two of the compounds; or a mixture containing at least two of the simple substances, the compounds, and the mixtures.

4. The thermoelectric direct conversion device according to claim 1, wherein the diffusion barrier layer is formed of at least one substance selected from the group consisting of (a) a layered complex oxide composed of cobalt and one substance selected from the group consisting of copper oxide, carbon, boron, sodium, and calcium, (b) aluminum nitride, (c) uranium nitride, (d) silicon nitride, (e) molybdenum disulfide, (f) a thermoelectric conversion material containing a cobalt antimonide compound having a skutterudite crystal structure as the principal phase, (g) a thermoelectric conversion material containing a clathrate compound as the principal phase, and (h) a thermoelectric conversion material containing a half-Heusler compound as the principal phase; a compound composed of at least two of the substances (a) to (h); a mixture containing at least two of the substances (a) to (h); and a solid solution composed of at least two of the substances (a) to (h).

5. The thermoelectric direct conversion device according to claim 4, wherein the half-Heusler compound is a thermoelectric direct conversion semiconductor substance containing at least one element selected from the group consisting of titanium, zirconium, hafnium, nickel, tin, cobalt, antimony, vanadium, chromium, niobium, tantalum, molybdenum, palladium, and rare earth elements.

6. The thermoelectric direct conversion device according to claim 1, wherein the inert gas comprises at least one gas selected from the group consisting of nitrogen, helium, neon, argon, krypton, and xenon, and is placed at a pressure lower than a pressure of the environmental atmosphere at room temperature.

7. The thermoelectric direct conversion device according to claim 1, wherein the p-type semiconductors and the n-type semiconductors are thermoelectric direct conversion semiconductors comprising at least three elements selected from the group consisting of rare earth elements, actinoids, cobalt, iron, rhodium, ruthenium, palladium, platinum, nickel, antimony, titanium, zirconium, hafnium, nickel, tin, silicon, manganese, zinc, boron, carbon, nitrogen, gallium, germanium, indium, vanadium, niobium, barium, and magnesium.

8. The thermoelectric direct conversion device according to claim 1, wherein the p-type semiconductors and the n-type semiconductors have a crystal structure as principal phase selected from the group consisting of a skutterudite structure, a filled skutterudite structure, a Heusler structure, a half-Heusler structure, and a clathrate structure, and mixed phases of these.

9. The thermoelectric direct conversion device according to claim 1, wherein the diffusion barrier layers are formed on the high-temperature electrodes and/or the low-temperature electrodes.

10. The thermoelectric direct conversion device according to claim 1, wherein the metal cover and the metal frame are made of a material selected from the group consisting of nickel, a nickel-based alloy, carbon steel, stainless steel, an iron-based alloy containing chromium, an iron-based alloy containing silicon, an alloy containing cobalt, and an alloy containing nickel or copper
